(19) United States
(12) Patent Application Publication
(10) Pub. No.: US 2017/0009349 A1
(43) Pub. Date: Jan. 12, 2017

(54) FACILITY AND METHOD FOR APPLYING COATINGS TO ELONGATED AUTOMOTIVE PARTS

(71) Applicant: PTI DOS DIVERSIFIED OUTSOURCING SOLUTIONS S DE RL DE CV, Silao (MX)

(72) Inventors: Zafar Iqbal, Silao (MX); David Salazar Yanez, Silao (MX)

(21) Appl. No.: 15/184,468

(22) Filed: Jun. 16, 2016

(30) Foreign Application Priority Data
Jun. 19, 2015 (MX) MX/A/2015/008132

(51) Int. Cl. C23C 16/56

(52) U.S. Cl. CPC C23C 16/56

(57) ABSTRACT

An installation and a method for applying coatings to automotive enlarged pieces are disclosed. The installation comprises an elevated conveyor, wherein the enlarged pieces are vertically hanged up; a formation section of an anticorrosive coating on the surface of the enlarged piece; a drying section of the enlarged piece on which the coating has been formed; a masking section wherein some portions of the piece are covered; a paint application section wherein the enlarged piece is coated with paint; an unmasking section of the piece in which the previous masked portions are uncovered; wherein the elevated conveyor continuous and vertically conveys the enlarged pieces along each of the sections in the installation.

### TECHNICAL FIELD

The instant invention refers to techniques which are used in the design and manufacturing of components and automotive parts for the Automotive Industry and more particularly, refers to an installation and a method for application of coatings on enlarged pieces, preferably automotive shafts.

### BACKGROUND OF THE INVENTION

Automotive industry is a worldwide industry with great dynamism which daily has new and improved technologies. Furthermore, the requirements demanded by the consumers and the guarantee which assembly plants must provide are greater and greater, for example, the time a component must function without a failure. In this sense, guarantees including several years, tens of thousands of kilometers or even lifetime guarantees are usual.

One of such guarantees is demanded for the powertrain of the automobiles, including components such as the drive shafts (those responsible for transmitting power to the wheels) and axles connecting together the rear or front wheels. In this sense, the shafts and axles are exposed to the weather and they are subjected to high stresses, thus the manufacturing metal must be absolutely protected with anticorrosive coatings for ensuring a large duration without failures in the piece.

It is also important to mention that the assembly plants require an even quality in their products from the automotive parts providers and also the assembly pants require a delivery time guarantee, furthermore it is logical to think that in the case of an increase of the automobile demand, the automotive parts providers also must increase their fabrication capacity in order to satisfy such demand.

In the past just before present invention, the application of coatings and paint to the shafts and axles generally was performed in a manual manner by means of tools, treating the piece in a horizontal position along all the required stages in order to form the coating, this traditional manner of manipulating the pieces involves many disadvantages, as the limitation in the number of pieces which may be finished in a working day or the necessary area in an installation when increasing the demand due the manipulation of said pieces in an horizontally manner require of a greater area.

In addition, treating said pieces in a manual manner, even with automatic equipment and tools, does not guarantee a constant quality in the pieces due the application of a coating or paint may vary depending on the operator performing the corresponding stage of the process.

In addition, both the shafts and axles have an enlarged geometry, that is, the distance from end to end of the piece is notably higher relative to the width or diameter thereof, so that applying coatings to this type of geometries is not an easy task as apparently could be at the beginning, since the paint could wring out. Besides, a shaft or axle has movable components or parts for their interconnection with other parts of the powertrain as for example the drive (transmission) or the wheels, said parts of the shaft do not require a coating, and even their structure avoid coating other portions of the shaft or axle.

Additionally, another important issue which has not been considered is that concerning to the designs of said enlarged pieces, particularly, the shafts which may vary their length and specific components, thus an installation must be designed in order to hand different models of shafts and the necessary changes must be provided in short time or even immediately.

In conclusion, the possibility of conceptually changing the traditional manner for forming coatings in automotive enlarged pieces has not been considered, thus being a challenge to the inventors during the development of present invention, wherein the challenge was solved as it will disclosed below.

The technical problem also may be set forth in this manner: the traditional way of forming coatings in shafts is not more a solution for providing coated pieces in a practical, intensive and economical way.

### SUMMARY OF THE INVENTION

In order to solve the problems of the prior art, the present invention provides an installation for applying coatings to automotive enlarged pieces in a practical and economical way for obtaining a greater number of coated pieces per time unit, particularly, the installation of the present invention comprises: an elevated conveyor, wherein the enlarged piece is vertically hanged up; said conveyor is very important due it allows to automatically move the pieces along all the sections integrating the installation, namely:

A forming section of an anticorrosive coating, wherein first it is cleaned the surface of the piece on which the anticorrosive coating is being formed on the surface of the enlarged piece; this section allows the formation of a coating preferably a phosphate coating for providing protection against corrosion.

After this anticorrosive coating formation section, there is a drying section of the enlarged piece on which the phosphate coating has been formed. In a preferred embodiment, the drying section comprises at least a hot air blower oriented to the enlarged pieces for drying any humidity, which remains in the enlarged piece from the previous section. In addition, manual air blowers may be provided in order to reach the same goal during this step.

Another section of the installation, is a masking section in which some portions or parts of the enlarged pieces are covered, for this purpose masks with predesigned geometries are used, said masks being coupled to and cover said portions, the predesigned masks are manually placed and, after being used, they still have a shelf life for masking more enlarged pieces coming from the previous section of the installation.

An important part of the installation, is a paint application section, wherein the masked piece is coated with paint, which purpose is i) promoting the aesthetic appearance of the piece, ii) inhibiting corrosion of the base metal and iii) promoting the structural resistance of the piece for accomplishing the life cycle of the piece which is offered in guarantees; for this step, preferably a first robot for properly coating and painting the surface of a target enlarged piece, in a short time, is used. In another embodiment and, depending on the particular geometry of the enlarged piece, a second robot is included.

In other embodiment, the painting station comprises a drying subsection, which includes infrared emission bars, which heat the enlarged pieces after being painted by the robot, or the robots, this subsection also, may comprise convection hot air applicators, being oriented to the recently painted surface. The goal of this subsection is increasing the temperature of the base metal and promoting the drying of the paint liquid layer from inside to outside, thus generating an instantaneous fastening or adhesion effect in order to prevent the wring out of the paint due gravity.

The installation of present invention also comprises a piece unmasking section, wherein the previously masked portions are uncovered; in this section, a protector substance against oxidation is also optionally applied.

As mentioned, the elevated conveyor continuous and vertically conveys the enlarged piece along each of the installation sections and, more preferably, the painting section includes a gear mechanism for angularly rotating the piece on its axis. The enlarged pieces, which may be processed with present invention, are selected from the group comprising shafts, semi-shafts, drive shafts, prop shafts and half shafts.

Preferably, in the masking section the bearings of the shaft, weld yokes, spline yokes, the constant speed joints (CV Joint), central bearings, brackets, tubes or spiders are masked.

In other aspect of the invention, it is provide a method for applying a coating to an automotive enlarged piece, the method of present invention comprising vertically hanging up the enlarged piece in an elevated conveyor; then an anticorrosive coating on the surface of the enlarged piece is formed; subsequently, drying the piece on which the coating of the previous step has been formed; then some portions of the enlarged piece are masked. Afterwards the masking step, a very important step consisting in the application of paint to the masked piece is performed; finally, the previously masked portions are unmasked; it is convenient to mention that the elevated conveyor continuous and vertically conveys the enlarged piece along each of the steps of the process.

In order to paint different shapes of enlarged pieced particularly in shafts and in order to apply the coating no matters the model of piece being conveyed; in an embodiment, the method comprises detecting the length of the enlarged piece previous entering the painting step, wherein according to the size of the enlarged piece a determined program for application of paint during the painting step is executed.

In other embodiment and in order to prevent running of the paint, after the paining step, the pieces are heated for drying the paint from inside to outside. The heating is carried out by means of infrared or hot air circulating by convection.

### BRIEF DESCRIPTION OF THE FIGURES

The novel aspects, which are characterizing of present invention, will be now established, particularly in the attached claims. However, the invention together with other goals and advantages thereof should be better understood in the below detailed description of some preferred embodiments of the invention, when reading together with the figures, in which:

FIG. 1 is a perspective view of the enlarged pieces of different design and geometry, which may be handled in the installation of present invention;

FIG. 2 is a flowchart showing the arrangement between the distinct sections comprised by the present invention;

FIG. 3 shows the section for application of a phosphate coating;

FIG. 4 is a flowchart showing the first robot and the second robot in the painting section;

FIG. 5 shows a view of the spline yoke once masked with a predesigned piece for such purpose; and

FIG. 6 shows a flowchart of an embodiment of the method of present invention.

### DETAILED DESCRIPTION OF THE PREFERRED EMBODIMENTS OF THE INVENTION

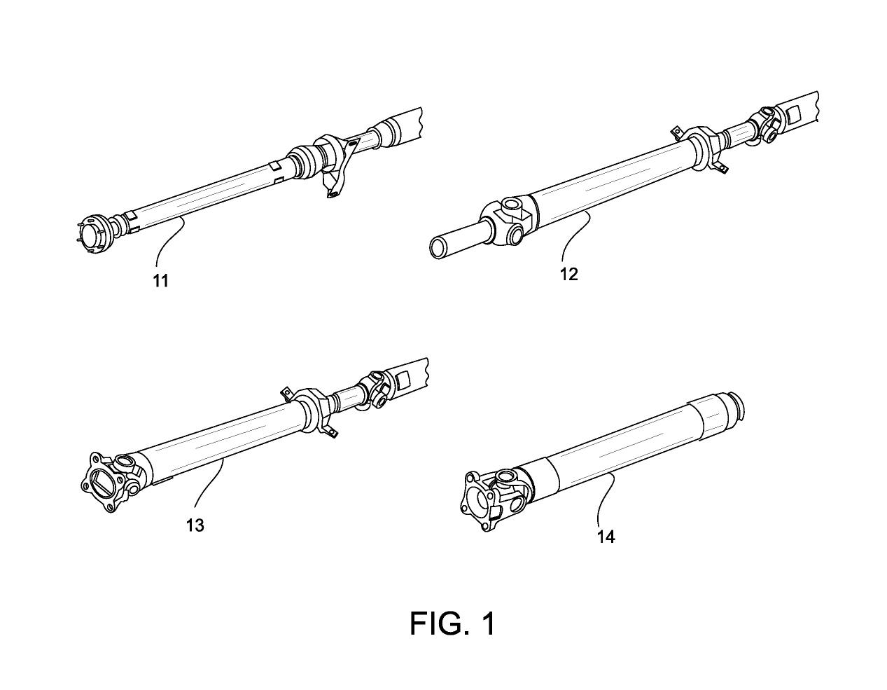

Referring to FIG. 1, there are four types of enlarged pieces, which are identified with reference numbers 11, 12, 13 and 14, wherein by means of installation of present invention a coating may be applied thereon.

For example, the piece 11 is a shaft for a lightweight vehicle type “crossover”, which transmits torque and movement of the transmission to the rear axis and containing a typical length of only a few centimeters. On the other hand, the piece 12 is a drive shaft for a lightweight truck being used in integral traction vehicles in the four wheels, in said figure the shaft includes a welded fork, bearings and a spline yoke which serves for connecting the radial movement of the transmission and flexibly coupling with the transmission and the axis, as well as torque transmission.

Besides, shafts 13 and 14 are shafts used for the same case that shaft 12. It is convenient to point out that within the automotive industry there are shafts with one, two or three sections and their use may be directed to lightweight vehicles, heavyweight equipment and all of them may be processed in the installation of present invention for the formation of a coating over the pieces.

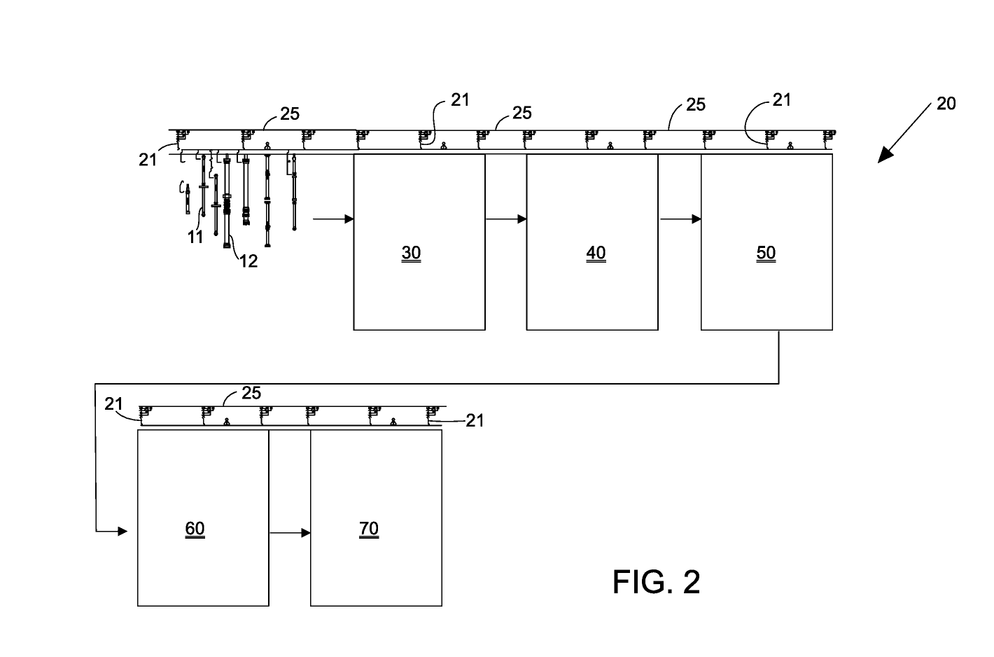

Now, referring to FIG. 2, it is shown an installation arrangement 20 of present invention, wherein an elevated conveyor 25 is seen, said conveyor conveys the pieces along each of the following working sections, including:

An anticorrosive coating formation section 30, which may be a phosphate anticorrosive coating on the surface of the enlarged piece 11, 12; generating an amorphous surface with microscopic crystals for receiving paint, thus generating a higher adherence effect (microscopic Velcro effect). Afterwards section 30, there is a drying section 40 of the enlarged piece on which the coating in section 30 has been formed. Afterwards the drying section, there is a masking section 50, wherein some portions of the already dried enlarged component are covered.

FIG. 2 also shows a paint application section 60, wherein the enlarged piece is coated with paint, once the shafts have been painted they pass through a unmasking section 70 of the piece, wherein the previously masking portions are uncovered; in this section, there are antioxidant substances reservoirs, being the antioxidant substances optionally applied.

It is too important to emphasize that the elevated conveyor 25 continuous and vertically conveys the pieces, by means of hooks 21 along each of the sections 30, 40, 50, 60 and 70 of the installation, for which the height of the conveyor is sufficient for separating the enlarged pieces relative to the floor as well as the pieces are examined and manipulated by the operators. Preferably, the separation between the hooks is at least 30.54 cm, allowing the separation to position a large number of pieces in the conveyor per length unity; additionally, the separation allows an independent manipulation of each piece separately in each of the sections without an interference of two consecutive pieces therebetween.

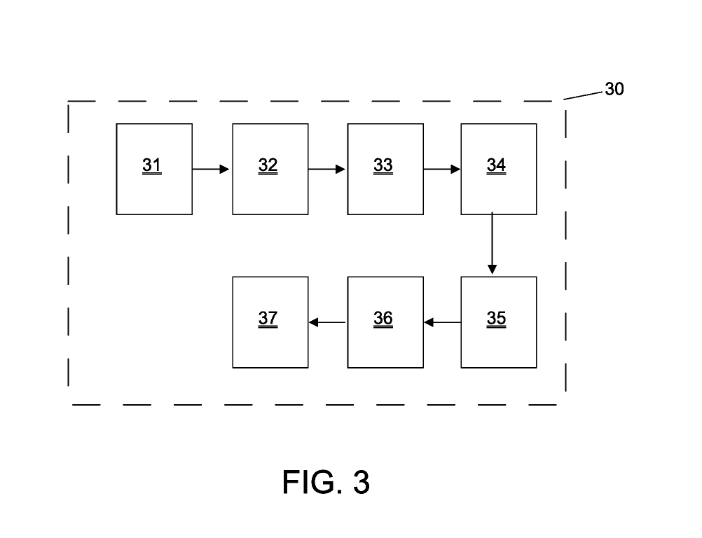

Referring to FIG. 3, there are shown different sections being part of the formation station 30 of the phosphate anticorrosive coating, including:

a degreasing station 31, wherein a degreasing substance is applied to the piece, then there is a first rinsing station 32 located afterwards the degreasing station 31 for eliminating any trace of the degreasing substance, subsequently there is shown an conditioner station 33 located afterwards the first rinsing station 32; once the piece has passed through the conditioner application station, the piece passes through a phosphate application station 34; then there is a phosphate rinsing station 35 afterward the phosphate application station; in order to continue forming the coating, there is a seal application station 36 afterwards the phosphate rinsing station; and finally, a deionized-water application station 37, afterwards the seal application station. One skilled in the art would note that the substances used within each of stations 31-37 are already known, being said section only a portion of the installation, wherein the pieces vertically pass therethrough.

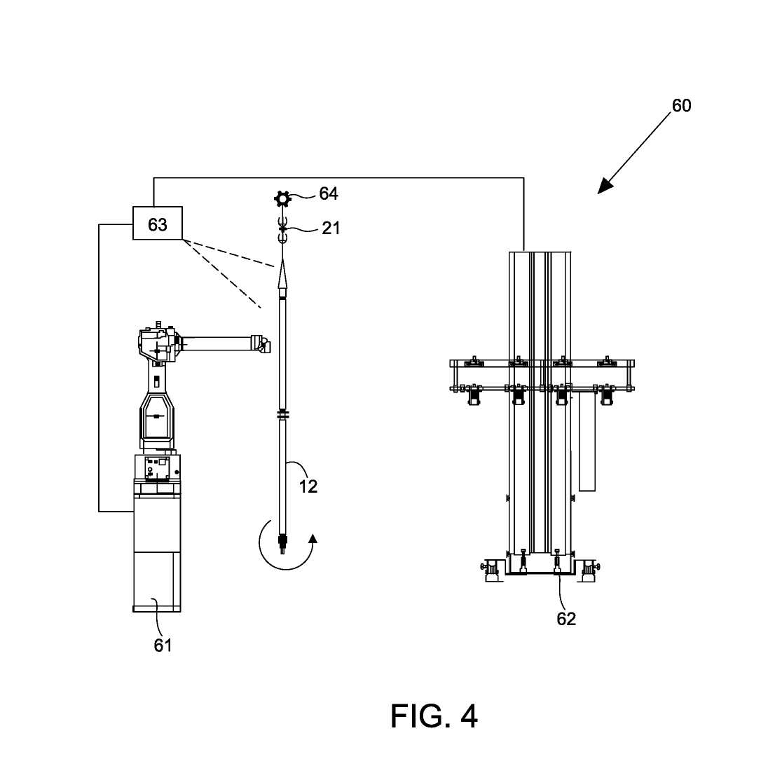

Now, referring to FIG. 4, a pair of robots 61 and 62 are shown, which are located in the painting section 60, said robots are a first robot 61 with multi-axial movement in three axis in order to paint the largest portion of the surface of shaft 12. Then, if necessary, and depending on the length of the shaft, the shaft passes to a second robot 62 being reciprocating, the robot 62 paints the shaft in those portions which were not coated by the first robot 61. Therefore, depending on the geometry of the piece, one or both robots are used.

The instant invention, provides a sensor 63 detecting the length of the enlarged piece, the sensor being located previous the painting section 60, said sensor allows detecting the size of piece 12 which enters into the painting section, said sensor is operatively connected to robot 61 and/or 62 determining the manner in which the paint must be specifically applied, which unmistakably represents an advantage due in the case a piece entering to the painting section has a distinct length to that already within the painting section, the corresponding piece entering to the painting section receives the necessary amount of paint without changing the installation.

Conveyor comprises gears 64 connected to hooks 21, which radially rotate the enlarged pieces over their axis in the painting section 60, wherewith the paint is applied in a controlled and homogenous way on the surface of the piece to be painted.

It is too important to state that, in an embodiment of the invention, the painting station comprises a drying subsection, which includes infrared emission bars heating the pieces afterwards the pieces have been painted by the first robot 61, said subsection also may comprise convection hot air applicators oriented to the recently painted surface. The goal of said subsection is to raise the temperature of the metal base and promoting the drying of the paint liquid layer from inside to outside, thus generating an instantaneous fastening or adhesion effect in order to prevent running of the paint due gravity as consequence of the vertically positioning of the pieces in the conveyor.

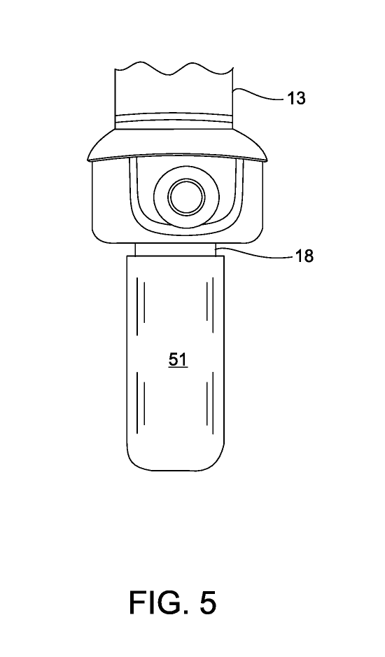

Now referring to FIG. 5, in which it is shown the placing of the masks 51 in some parts of shaft 13, as for example the spline yoke 18, this parts are made of silicone in order to use them more than one time, e.g. the parts may be used about at least 500 thousand times. In this section, an antioxidant coating as Ferrocote® or other similar substances stored in reservoir may be applied.

As an exemplary comparative data, the installation of the present invention may finish from 300 to 350 pieces per hour, while the traditional techniques are able to finish only from 80 to 120 pieces, using the same amount of workers in an installation with the same surface area.

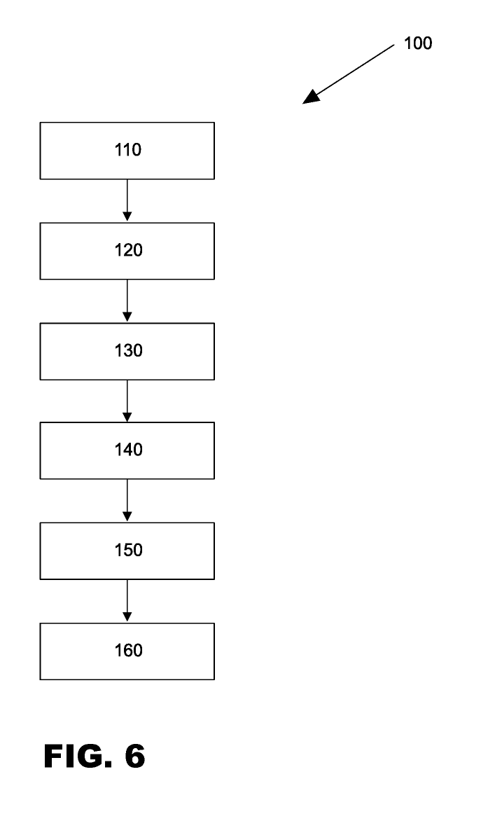

Now referring to FIG. 6, it is shown a flowchart of method 100 for applying a coating to an enlarged piece, according to present invention, which begins in step 110, wherein the enlarged pieces are hanged out in an elevated conveyor. Then, in step 120 an anticorrosive coating on the surface of the enlarged piece is formed; then, in the step 130, the piece on which the coating has been formed during step 120 is dried. Subsequently, in step 140, some portions of the enlarged piece are masked; afterwards, in step of painting 150 some paint to the masked piece is applied. Finally, in step 160 the previously masked portions are unmasked.

In the method of the present invention, the presence of the elevated conveyor is necessary due the conveyor continuous and vertically conveys the elevated piece along each of the steps of the method.

An embodiment of the method comprises detecting the length of the enlarged piece previous passing to the painting step; such detection allows to perform the necessary adjustments in the painting station (robots) in order to, no matters the length of the piece, apply the paint in the required way. In step of painting 150, the pieces are axially rotated as they are painted, thus facilitating the coating of the surface necessary to be painted. The rotation speed is performed depending on the diameter of the piece.

In a further embodiment of the method of present invention, after the paint is applied, the pieces are heated for drying the paint from inside to outside. Therefore, the heating is performed by means of infrared or hot air circulating by convection.

As can be seen, the instant invention conceptually changes the traditional mode of forming coatings on enlarged pieces, due the pieces are vertically hanged out, furthermore the necessary elements and steps for handling the pieces in such way are provided, the installation being flexible for manipulating pieces with different geometries and for finishing a large number of pieces with the coating applied.

Even when some preferred embodiments of present invention have been disclosed and exemplified, it is notable that there are numerous modifications which may be done in said embodiments, such as the type of enlarged pieces on which the coating will be formed, the shape of the hook required for hanging up the shaft, the type of specific mask depending on the piece, the use of one or two robots. Therefore, present invention must not be considered as limitative except for the state of the art and the scope of the attached claims.

### REFERENCE LIST

11, 12, 13, 14 Shafts
18 Spline yoke
20 Installation
21 Hooks
25 Elevated Conveyor
30 Anticorrosive coating formation section
31 Degreasing station
32 Rinsing section station
33 Conditioner application station
34 Phosphate application station
35 Phosphate rinsing station
36 Seal application station
37 Deionized water application station
40 Drying section
50 Masking section
51 Mask
60 Paint application section
61 First robot
62 Second robot
63 Length sensor
64 Rotating gears
70 Unmasking section
100 Application method
110 Step of hanging up pieces in conveyor
120 Step of application of anticorrosive coating
130 Step of drying
140 Step of masking
150 Step of painting
160 Step of unmasking

1. An installation for applying coatings to automotive enlarged pieces, characterized in that it comprises:
a) an elevated conveyor, wherein the pieces are vertically hanged up;
b) an anticorrosive coating formation section on a surface of the enlarged piece;
c) a drying section of the piece on which a coating in section b) has been formed;
d) a masking section for covering determined portions of the piece;
e) a paint application section, wherein the masked piece is coated with paint; and
f) an unmasking section of the piece, wherein the previously masked portions are uncovered,
wherein the elevated conveyor continuous and vertically conveys the enlarged piece along each of the installation sections.

2. The installation according to claim 1, characterized in that, in the elevated conveyor, each enlarged piece is separated from each other to a minimum distance of 30.54 cm.

3. The installation according to claim 1, characterized in that, the coating formation section comprises:
a degreasing station;
a first rinsing station located afterwards the degreasing station;
a conditioner application station located afterwards the first rinsing station;
a phosphate application station located afterwards the conditioner application station;
a phosphate rinsing station located afterwards the phosphate application station;
a seal application station located afterwards the phosphate rinsing station; and
a deionized water application station located afterwards the seal application station.

4. The installation according to claim 1, characterized in that, the drying section comprises at least a hot air blower oriented to the enlarged piece for eliminating any trace of liquid from the previous section.

5. The installation according to claim 4, characterized in that, the installation further comprises manual air blowers operated for withdrawing any trace of liquid.

6. The installation according to claim 1, characterized in that, the enlarged piece is a shaft selected from the group comprising shafts, semi-shafts, drive shafts, prop shafts and half shafts.

7. The installation according to claim 1, characterized in that, the portions of the piece that are covered are selected from the bearings of a shaft, weld yokes, spline yokes, constant speed joints (CV Joint), central bearings, brackets, tubes and spiders.

8. The installation according to claim 1, characterized in that, the masking section includes predesigned masks that are place in the sections of enlarged pieces which should not be painted.

9. The installation according to claim 1, characterized in that, the painting section comprises:
a first robot with movement in three axles for applying paint.

10. The installation according to claim 9, characterized in that, the installation further comprises:
a second robot with reciprocating movement for coating those areas non-coated of the piece by the first robot.

11. The installation according to claim 1, characterized in that, the painting section comprises a drying subsection which includes infrared emission bars or convection hot air applicators for heating the pieces from inside to outside after the pieces have been painted.

12. The installation according to claim 1, characterized in that, in the unmasking station there are provided antioxidant material reservoirs.

13. The installation according to claim 10, characterized in that, the installation comprises a length sensor of the enlarged piece arranged previous the painting section, allowing the sensor to detect the size of the piece entering into the painting section, being the sensor operatively connected to the first and/or second robot determining the way in which paint must be applied.

14. The installation according to claim 1, characterized in that, the conveyor comprises gears which radially rotate the enlarged piece in the painting section.

15. A method for applying a coating to an automotive enlarged piece, the method being characterized in that, it comprises the following steps:
a) vertically hanging up the enlarged piece in an elevated conveyor;
b) forming an anticorrosive coating on the surface of the enlarged piece;
c) drying the piece on which the coating in step b) has been formed;
d) masking some portions of the enlarged piece;
e) applying paint to the masked piece;
f) unmasking the previous masked portions;
wherein the elevated conveyor continuous and vertically conveys the enlarged piece along each of the steps of the method.

16. The method according to claim 15, characterized in that, the method additionally comprises:
detecting the length of the enlarged piece previous entering the painting step.

17. The method according to claim 15, characterized in that, in the painting step, the enlarged pieces are axially rotated while they are painted.

18. The method according to claim 17, characterized in that, the rotation speed of the pieces is performed based on the diameter of the piece.

19. The method according to claim 15, characterized in that, afterwards receiving the paint, the pieces are heated for drying the paint from inside to outside.

20. The method according to claim 19, characterized in that, the heating is performed by means of infrared or hot air circulating by convection.
